(19) United States
(12) Patent Application Publication
(10) Pub. No.: US 2003/0017670 A1
(43) Pub. Date: Jan. 23, 2003

(54) Method of manufacturing a semiconductor memory device with a gate dielectric stack

(75) Inventors: Tuung Luoh, Kaohsiung (TW); Chin-Hsiang Lin, Nan-Tao (TW); Yaw-Lin Hwang, Taipei (TW)

Correspondence Address: LOWE HAUPTMAN GILMAN & BERNER, LLP, 1700 Diagonal Road, Suite 310, Alexandria, VA, 22314, US

(73) Assignee: Macronix International Co., Ltd.

(21) Appl. No.: 09/908,704

(22) Filed: Jul. 20, 2001

(51) Int. Cl. H01L 21/336; H01L 21/31; H01L 21/469

(52) U.S. Cl. 438/257; 438/265; 438/769

(57) ABSTRACT

A method of manufacturing a semiconductor memory device with a gate dielectric stack is provided. A first insulating layer is formed on a semiconductor substrate with a first conductive type. A first conductive layer is formed on the first insulating layer. A second insulating layer with a stack of silicon dioxide/silicon nitride/silicon oxynitride/silicon dioxide is formed on the first conductive layer. A second conductive layer is formed on the second insulating layer. Patterning the first insulating layer, the first conductive layer, the second insulating layer and the second conductive layer to form a first gate dielectric layer, a floating gate, a second gate dielectric layer and a control gate. A source/drain with a second conductive type beside the floating gate is formed in the semiconductor substrate.

### BACKGROUND OF THE INVENTION

1. Field of the Invention

The present invention relates in general to a method for fabricating a semiconductor device, and more particularly, to a method for fabricating a high-reliability dielectric layer for a semiconductor memory device.

2. Description of the Prior Art

In conventional stacked non-volatile semiconductor memory devices, an insulating layer for insulating a floating gate and a control gate from each other is a single layer of silicon dioxide, which is referred to as a second gate insulating layer. The semiconductor devices tend to be miniaturized more and more, and in this situation the thickness of the second gate insulating layer is required to further decrease.

Since the ONO layer, having a stacked structure consisting of a silicon oxide layer/a silicon nitride layer/a silicon oxide layer, has a good withstanding voltage characteristic even with a relatively thin layer thickness. The memory cell of the semiconductor memory device having the ONO layer also has an improved retention characteristic. The ONO layer is used instead of a single layer of silicon dioxide as the second gate insulating layer. The current method of forming the ONO layer involves growing a thermal oxide layer over polysilicon. Then, a nitride layer is deposited overlying the thermal oxide layer. After the nitride layer is deposited, either the top surface of the nitride layer is oxidized, or an oxide layer is deposited overlying the nitride layer.

However, in order to remain cost competitive, the semiconductor devices are continually scaled down to increase effective device densities. In this circumstance, the ONO layer becomes thin enough to pose problems of pinholes and poor electrical qualities of the silicon nitride layer, thus causing low breakdown voltages and current leakage, that adversely affecting the reliability of the semiconductor memory device.

Accordingly, it is an intention to provide a polygate dielectric layer for use in semiconductor memory devices that can provide higher withstanding voltages and retention characteristics as the polygate dielectric layer is reduced.

### SUMMARY OF THE INVENTION

It is an objective of the present invention to provide a method for manufacturing a semiconductor memory device with a gate dielectric stack of silicon dioxide/silicon nitride/silicon oxynitride/silicon dioxide layer, which provides a higher withstanding voltage, lower current leakage and improved retention characteristic of a memory cell.

It is anther objective of the present invention to provide a method for forming a gate dielectric stack of silicon dioxide/silicon nitride/silicon oxynitride/silicon dioxide by a single-wafer thermal process.

It is a further objective of the present invention to provide a method for manufacturing a semiconductor memory device with a gate dielectric stack, which can reduce the structural stress.

In order to achieve the above objectives, the present invention provides a method of manufacturing a semiconductor memory device with a gate dielectric stack. A first insulating layer is formed on a semiconductor substrate with a first conductive type. A first conductive layer is formed on the first insulating layer. A second insulating layer by sequentially stacking a first silicon dioxide layer, a silicon nitride layer, a silicon oxynitride layer and a second silicon dioxide layer is formed on the first conductive layer. A second conductive layer is formed on the second insulating layer. Patterning the first insulating layer, the first conductive layer, the second insulating layer and the second conductive layer to form a first gate dielectric layer, a floating gate, a second gate dielectric layer and a control gate on the semiconductor substrate. A source/drain with a second conductive type is then formed in the semiconductor substrate beside the floating gate.

### BRIEF DESCRIPTION OF THE DRAWINGS

The foregoing and other advantages and features of the invention will be apparent from the following more particular description of the preferred embodiments of the invention, as illustrated in the accompanying drawings.

FIG. 1 to FIG. 2 shows schematic cross-sectional views of various steps for forming the present semiconductor memory device;

FIG. 3 depicts a process flow for forming a gate dielectric stack according to one first embodiment of the present invention; and

FIG. 4 depicts a process flow for forming a gate dielectric stack according to a second embodiment of the present invention.

### DESCRIPTION OF THE PREFERRED EMBODIMENTS

The present invention provides a structure of a non-volatile semiconductor memory device with a gate dielectric stack and the method of the same. The present method can provide either an N channel non-volatile semiconductor memory device or a P channel non-volatile semiconductor memory device.

The present invention will be described in more detailed below.

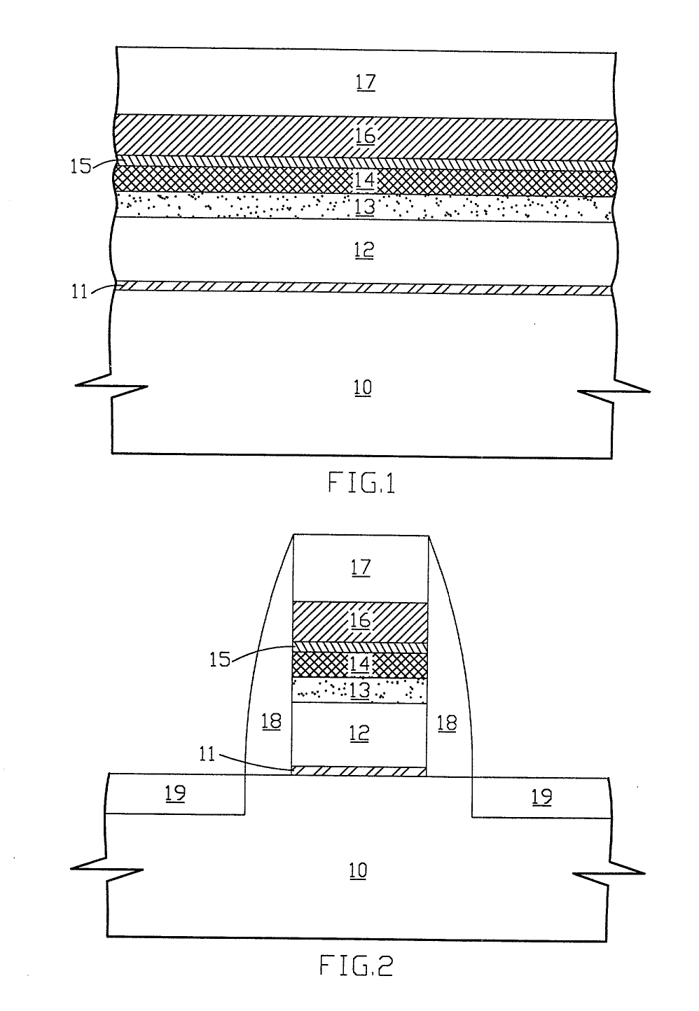

Referring to FIG. 1, a semiconductor substrate 10 with P conductivity, such as a P type silicon substrate, is provided. The active regions are defined on the semiconductor substrate 10 by the conventional photolithography and etching method. Each active region is formed between a pair of isolated regions, such as field oxide regions, in the present invention. A first insulating layer 11 is formed on the active region over the semiconductor substrate 10. The first insulating layer 11 can be a tunnel oxide layer formed by thermal oxidation. A first conductive layer 12 is formed on the first insulating layer 11. The first conductive layer 12 can be a polysilicon layer formed by the conventional low pressure chemical vapor deposition (LPCVD) method. A second insulating layer is formed by sequentially stacking a first silicon dioxide layer 13, a silicon nitride layer 14, a silicon oxynitride layer 15 and a second silicon dioxide layer 16 on the first conductive layer 12. Thereby, the second insulating layer has a stack structure of silicon dioxide/silicon nitride/silicon oxynitride/silicon dioxide. A second conductive layer 17 is then formed on the second insulating layer. The second conductive layer 17 can be a polysilicon layer formed by the conventional LPCVD method.

Referring to FIG. 2, patterning the first insulating layer 11, the first conductive layer 12, the second insulating layer and the second conductive layer 17 by the conventional photolithography and etching method. A first gate dielectric layer, a floating gate, a second gate dielectric layer and a control gate are then formed over the semiconductor substrate 10. The second insulating layer is formed of the stack of the first silicon dioxide layer 13, the silicon nitride layer 14, the silicon oxynitride layer 15 and the second silicon dioxide layer 16. Therefore, the second gate dielectric layer formed of the second insulating layer provides a stack of silicon dioxide/silicon nitride/silicon oxynitride/silicon dioxide. An insulating spacer is formed on the sidewall of the floating gate and the control gate for protecting them. A source/drain 19 with N type dopants is formed beside the insulating spacer in the semiconductor substrate 10 by way of the conventional ion implantation technique. Accordingly, an N channel non-volatile semiconductor memory device with a gate dielectric stack is obtained.

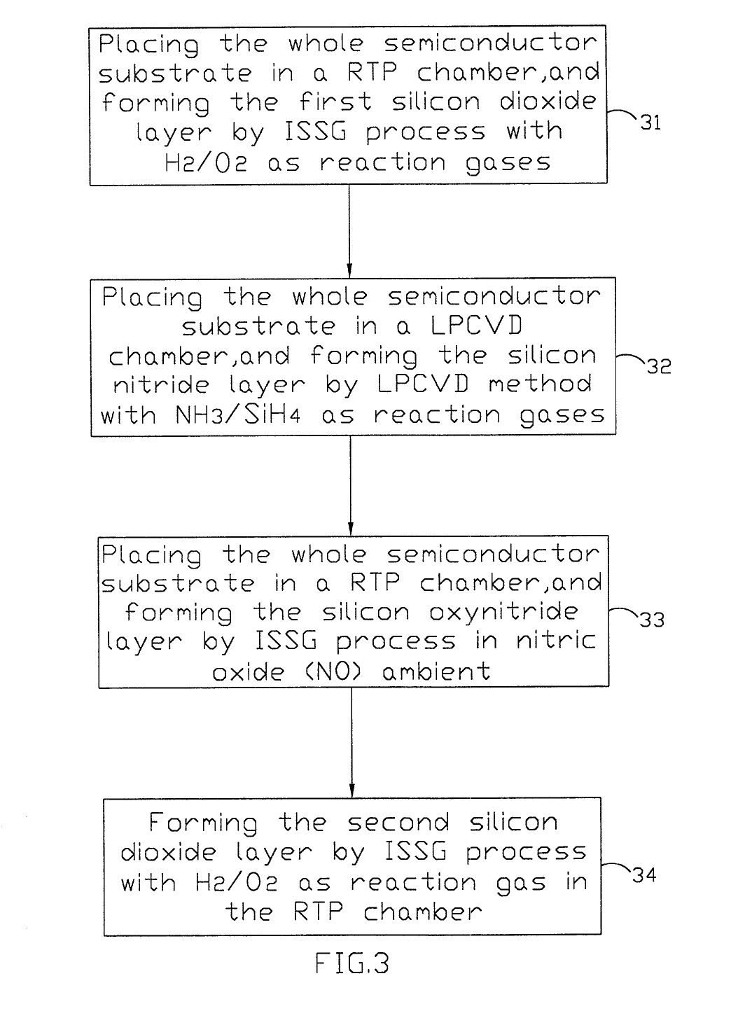

FIG. 3 is a process flow for forming the gate dielectric stack of silicon dioxide/silicon nitride/silicon oxynitride/silicon dioxide on the first conductive layer 12 formed of polysilicon, according to one first embodiment of the present invention. In step 31, the whole semiconductor substrate 10 is placed in a rapid thermal process (RTP) chamber. The first silicon dioxide layer 13 is formed on the first conductive layer 12 of polysilicon by an in-situ steam generation (ISSG) process with gas mixture of H₂/O₂ as reaction gases at a temperature of about 800° C. to about 1200° C. under a pressure of about 5 torr to about 20 torr. The flow ratio of H₂ in the gas mixture of H₂/O₂ is about 0.1˜40%. In step 32, the whole semiconductor substrate 10 is placed in a low pressure chemical vapor deposition chamber. The silicon nitride layer 14 is formed on the first silicon dioxide layer 13 by way of a low pressure chemical vapor deposition method utilizing gas mixture of NH₃/SiH₄ as reaction gases. In step 33, the whole semiconductor substrate 10 is placed in the rapid thermal process chamber. The silicon oxynitride layer 15 is formed on the silicon nitride layer 14 by an in-situ steam generation process in nitric oxide (NO) ambient at a temperature of about 700° C. to about 1200° C. and under a pressure of about 10 torr to about 760 torr for a period of time ranging from about 3 seconds to about 150 seconds. In step 34, the whole semiconductor substrate 10 is still placed in the rapid thermal process chamber. A second silicon dioxide layer 16 is formed on the silicon oxynitride layer 15 by an in-situ steam generation process with gas mixture of H₂/O₂ as the reaction gases.

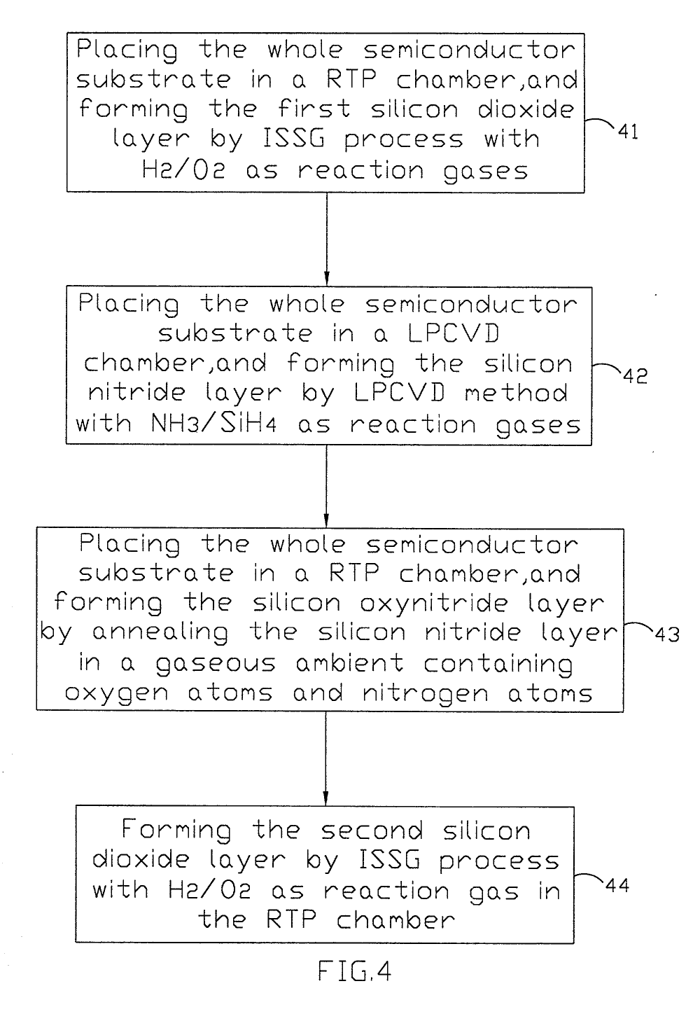

FIG. 4 is another process flow for forming the gate dielectric stack of silicon dioxide/silicon nitride/silicon oxynitride/silicon dioxide on the first conductive layer 12 formed of polysilicon, according to a second embodiment of the present invention. Steps 41, 42 and 44 are similar to steps 31, 32 and 34 of the first embodiment. In step 43, a rapid thermal process is performed instead of the in-situ steam generation process. The whole semiconductor substrate 10 is placed in a rapid thermal process chamber. The silicon oxynitride layer 15 is formed on the silicon nitride layer 14 by annealing the silicon nitride layer 14 in a gaseous ambient containing oxygen atoms and nitrogen atoms, such as nitrous oxide (N₂O) gas or nitric oxide (NO) gas, at a temperature of about 800° C. to about 1200° C. and under a pressure of about 10 torr to about 500 torr for a period of time ranging from about 5 seconds to about 180 seconds. The silicon nitride layer 14 also can be annealed in gas mixture of NH₃, SiH₄, N₂ and O₂ at a temperature of about 700° C. to about 1200° C., so as to form the silicon oxynitride layer 15.

A third embodiment of the present invention is to provide a gate dielectric stack of silicon dioxide/silicon oxynitride/silicon nitride/silicon oxynitride/silicon dioxide on the first conductive layer 12 formed of polysilicon. The difference between the third embodiment and the first embodiment is a silicon oxynitride layer is formed between the first silicon dioxide layer 13 and the silicon oxynitride layer 14. The method for forming the silicon oxynitride layer is the same with the silicon oxynitride layer 15. The whole semiconductor substrate 10 is placed in a rapid thermal process chamber, and the silicon oxynitride layer is formed on the first silicon dioxide layer 13 by an in-situ steam generation process in nitric oxide (NO) ambient at a temperature of about 700° C. to about 1200° C. and under a pressure of about 10 torr to about 760 torr. In alternate way, a rapid thermal process is performed instead of the in-situ steam generation process. The whole semiconductor substrate 10 is placed in a rapid thermal process chamber. The silicon oxynitride layer is formed on the first silicon dioxide layer 13 by annealing the silicon dioxide layer 13 in a gaseous ambient containing oxygen atoms and nitrogen atoms, such as nitrous oxide (N₂O) gas or nitric oxide (NO) gas, at a temperature of about 700° C. to about 1200° C. and under a pressure of about 10 torr to about 500 torr. Alternately, the first silicon dioxide layer 13 also can be annealed in gas mixture of NH₃, SiH₄, N₂ and O₂ at a temperature of about 700° C. to about 1200° C., so as to form the silicon oxynitride layer thereon. In the third embodiment, the methods for forming the first silicon dixoide layer 14, the silicon nitride layer 14, the silicon oxynitride layer 15 and the second silicon dioxide layer 16 are the same with the first embodiment.

For the gate dielectric stack of the present invention, the resultant thickness of the first silicon dioxide layer 13 is about 15 to 70 angstroms. The resultant thickness of the silicon nitride layer 14 is about 20 to 90 angstroms. The resultant thickness of the silicon oxynitride layer 15 is about 5 to 30 angstroms. The resultant thickness of the second silicon dioxide layer 16 is about 15 to 120 angstroms. While the resulant thickness of the silicon oxynitride layer between the first silicon dioxide layer and the silicon nitride layer is about 5 to 30 angstroms.

Both of the rapid thermal process (RTP) chamber and the low pressure chemical vapor deposition (LPCVD) chamber used in the present invention can be designed to a single-wafer chamber. They also can be easily integrated into one unit of equipment. Therefore, the gate dielectric stack of the present invention can be fabricated by way of a single-wafer thermal process.

The present invention provides a gate dielectric stack of silicon dioxide/silicon nitride/silicon oxynitride/ silicon dioxide to reduce or eliminate the pinhole problem found in the silicon nitride layer of a conventional ONO stacked dielectric layer. The gate dielectric stack of the present invention also can be formed of silicon dioxide/silicon oxynitride/silicon nitride/silicon oxynitride/silicon dioxide. The present invention also provides a non-volatile semiconductor memory device with a gate dielectric stack having improved electrical properties, particularly a higher withstanding voltage and lower current leakage, than a conventional semiconductor memory device with the ONO stacked polygate dielectric layer of comparable thickness.

The preferred embodiments are only used to illustrate the present invention, not intended to limit the scope thereof. Many modifications of the preferred embodiments can be made without departing from the spirit of the present invention.

What is claimed is:

1. A method of manufacturing a semiconductor memory device with a gate dielectric stack, comprising:
forming a first insulating layer on a semiconductor substrate having a first conductive type;
forming a first conductive layer on said first insulating layer;
forming a second insulating layer by sequentially stacking a first silicon dioxide layer, a silicon nitride layer, a silicon oxynitride layer and a second silicon dioxide layer on said first conductive layer;
forming a second conductive layer on said second insulating layer;
patterning said first insulating layer, said first conductive layer, said second insulating layer and said second conductive layer to form a first gate dielectric layer, a floating gate, a second gate dielectric layer and a control gate; and
forming a source/drain with a second conductive type beside said floating gate in said semiconductor substrate.

2. The method of claim 1, wherein said first conductive type is either of N type conductivity and P type conductivity.

3. The method of claim 1, wherein said first conductive layer comprises polysilicon.

4. The method of claim 1, wherein said silicon nitride layer is formed by way of a low pressure chemical vapor deposition method utilizing NH₃ and SiH₄ as reaction gases.

5. The method of claim 1, wherein said silicon oxynitride layer is formed by an in-situ steam generation (ISSG) process including processing said silicon nitride layer in a nitric oxide (NO) ambient at a temperature of about 700° C. to about 1200° C. and under a pressure of about 10 torr to about 760 torr for a period of time about 3 seconds to about 150 seconds.

6. The method of claim 3, wherein said first silicon dioxide layer is formed by an in-situ steam generation (ISSG) process with H₂/O₂ as reaction gases at a temperature of about 800° C. to about 1200° C. under a pressure of about 5 torr to about 20 torr.

7. The method of claim 6, wherein the flow ratio of H₂ in the H₂/O₂ reaction gases is about 0.1˜40%.

8. The method of claim 1, wherein said second silicon dioxide layer is formed by an in-situ steam generation (ISSG) process with H₂/O₂ as reaction gases.

9. The method of claim 1, wherein said silicon oxynitride layer is formed by annealing said silicon nitride layer in a gas mixture containing oxygen atoms and nitrogen atoms.

10. The method of claim 1, wherein said silicon oxynitride layer is formed by annealing said silicon nitride layer in a gas mixture containing NH₃, SiH₄, N₂ and O₂ at a temperature of about 700° C. to about 1200° C.

11. The method of claim 1, wherein said silicon oxynitride layer is formed by annealing said silicon nitride layer in a gas mixture containing oxygen atoms and nitrogen atoms at a temperature of about 700° C. to about 1200° C. and under a pressure of about 10 torr to about 500 torr for a period of time about 5 seconds to about 180 seconds.

12. The method of claim 1, wherein said silicon oxynitride layer is formed by annealing said silicon nitride layer in nitrous oxide (N₂O) gas.

13. The method of claim 1, wherein said silicon oxynitride layer is formed by annealing said silicon nitride layer in nitric oxide (NO) gas.

14. The method of claim 1, wherein said silicon oxynitride layer is formed by processing said silicon nitride layer in a single-wafer thermal process in a gas mixture containing nitrogen atoms and oxygen atoms.

15. The method of claim 1, further comprises a step of forming a silicon oxynitride layer between said first silicon dioxide layer and said silicon nitride layer.

16. The method of claim 15, wherein said silicon oxynitride layer between said first silicon dioxide layer and said silicon nitride layer is formed by an in-situ steam generation (ISSG) process including processing said first silicon dioxide layer in a nitric oxide (NO) ambient at a temperature of about 700° C. to about 1200° C. and under a pressure of about 10 torr to about 760 torr.

17. The method of claim 15, wherein said silicon oxynitride layer between said first silicon dioxide layer and said silicon nitride layer is formed by annealing said first silicon dioxide layer in a gas mixture containing NH₃, SiH₄, N₂ and O₂ at a temperature of about 700° C. to about 1200° C.

18. The method of claim 15, wherein said silicon oxynitride layer between said first silicon dioxide layer and said silicon nitride layer is formed by annealing said first silicon dioxide layer containing oxygen atoms and nitrogen atoms at a temperature of about 700° C. to about 1200° C. and under a pressure of about 10 torr to about 500 torr.

19. The method of claim 15, wherein said silicon oxynitride layer between said first silicon dioxide layer and said silicon nitride layer is formed by annealing said first silicon dioxide layer in nitrous oxide (N₂O) gas.

20. The method of claim 15, wherein said silicon oxynitride layer between said first silicon dioxide layer and said silicon nitride layer is formed by annealing said first silicon dioxide layer in nitric oxide (NO) gas.
